(19) United States
(12) Patent Application Publication
(10) Pub. No.: US 2009/0152713 A1
(43) Pub. Date: Jun. 18, 2009

(54) INTEGRATED CIRCUIT ASSEMBLY INCLUDING THERMAL INTERFACE MATERIAL COMPRISED OF OIL OR WAX

(76) Inventors: Ioan Sauciuc, Phoenix, AZ (US); Gregory M. Chrysler, Chadler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/959,053

(22) Filed: Dec. 18, 2007

(51) Int. Cl. H01L 23/36

(52) U.S. Cl. 257/713; 257/E23.101

(57) ABSTRACT

Embodiments of a thermal interface material layer comprised of an oil or a wax are disclosed. The thermal interface material may be used to thermally couple an integrated circuit die to a thermal component, such as a heat spreader. Other embodiments are described and claimed.

### FIELD OF THE INVENTION

The disclosed embodiments relate generally to thermal solutions for integrated circuits, and more particularly to a thermal interface material comprised of oil or wax.

### BACKGROUND OF THE INVENTION

To aid in cooling an integrated circuit (IC) die, the IC die may be coupled with a thermal component, such as a heat spreader or a heat sink. To thermally couple the IC die with a heat spreader or other thermal component, a layer of a thermal interface material (TIM) may be disposed between the die and heat spreader. Examples of thermal interface materials include solder, thermally conductive polymers (which typically include thermally conductive fillers to enhance their thermal performance), as well as combinations of these and other materials. The TIM is bonded to both a surface of the IC die and a surface of the heat spreader, although these respective surfaces may be coated with a wetting and/or barrier layer to facilitate adhesion (e.g., gold, nickel, as well as combinations of these and other metals). Factors which may affect the choice of a thermal interface material for a particular application include thermal performance, operating temperature, assembly requirements, and material costs, especially in view of the trend toward Lead-free solders, such as those containing Indium.

### BRIEF DESCRIPTION OF THE DRAWINGS

FIG. 1 is a schematic diagram illustrating an embodiment of an integrated circuit assembly including an oil or wax thermal interface layer.

FIG. 2 is a schematic diagram illustrating another embodiment of an integrated circuit assembly including an oil or wax thermal interface layer.

FIG. 3 is a schematic diagram illustrating a further embodiment of an integrated circuit assembly including an oil or wax thermal interface layer.

FIG. 4 is a schematic diagram illustrating yet another embodiment of an integrated circuit assembly including an oil or wax thermal interface layer.

### DETAILED DESCRIPTION OF THE INVENTION

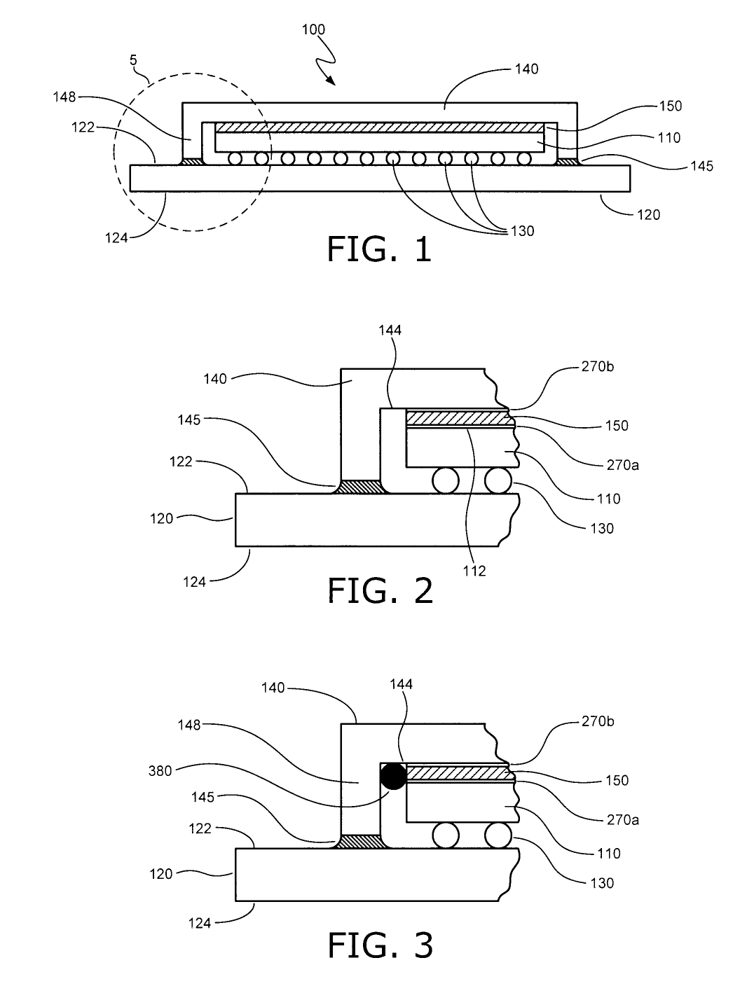

Illustrated in FIG. 1 is an embodiment of an integrated circuit (IC) package 100 including an oil or wax thermal interface material (TIM) 150. The IC package 100 may comprise any type of computing device. For example, the assembly 100 may comprise (or form part of) a hand-held computing device, a mobile computing device, a wireless communications device, a laptop computer, a desk-top computer, a server, etc. The IC package includes an integrated circuit die 110 that is disposed on and electrically coupled with a substrate 120. A heat spreader 140 (or other thermal component) is thermally coupled to a surface of die 110 by the oil or wax TIM layer 150. In some embodiments, an oil or wax TIM may provide a thermal performance that is comparable to (or perhaps better than) traditional thermal interface materials, such as the aforementioned solders and thermally conductive polymers. However, in other embodiments, an oil or wax TIM may provide a thermal performance that is less than that provided by these traditional thermal interface materials. Various embodiments of an assembly including an oil or wax TIM are described below in greater detail.

As noted above, the IC package 100 includes an integrated circuit die 110. The IC die 110 may comprise any suitable processing system, such as a microprocessor, a network processor, a graphics processor, a wireless communications device, a chipset, etc, as well as any combination of these and other systems or devices. In addition to IC die 110, one or more additional die and/or other components may be disposed in the assembly 100. Other components that may be disposed within IC package 100 include a memory (e.g., a flash memory, any type of Dynamic Random Access Memory, etc.), a memory controller, a voltage regulator, as well as passive components (e.g., capacitors, filters, antennas, etc.).

As previously set forth, die 110 is mechanically and electrically coupled with the substrate 120. The substrate 120 includes a first side 122 upon which the die 110 is disposed and an opposing second side 124. Substrate 120 may comprise any suitable type of substrate capable of providing electrical communications between the IC die 110 (and perhaps other components, as noted above) and a next-level component, such as a motherboard or other circuit board. Substrate 120 may also provide structural support for the die 110 (and other components). By way of example, in one embodiment, substrate 120 comprises a multi-layer substrate—including alternating layers of a dielectric material and metal—built-up around a core layer (either a dielectric or metal core). In another embodiment, the substrate 120 comprises a core-less multi-layer substrate. Other types of substrates and substrate materials may also find use with the disclosed embodiments (e.g., ceramics, sapphire, glass, etc.).

A number of interconnects 130 may extend between the IC die 110 and substrate 120. The interconnects 130 provide electrical connections between the die 110 and substrate 120, and these interconnects may also aid in mechanically securing the die to the substrate 120. In a further embodiment, a layer of underfill (not shown in figures) may be disposed between the IC die 110 and the substrate 120, and this underfill layer may also assist in securing the die to the substrate. The interconnects 130 may comprise any suitable type of interconnect and may comprise any suitable electrically conductive materials. According to one embodiment, the interconnects 130 comprise an array of solder bumps extending between the die 110 and substrate 120 (perhaps in combination with an array of Copper columns extending from die 110 and/or substrate 120). A solder reflow process may be utilized to form the interconnects 130 between the die 110 and substrate 120. According to another embodiment, the substrate 120 may comprise alternating layers of dielectric material and metal that are built-up around the die 110 itself, this process sometimes referred to as a “bumpless build-up process.” Where such an approach is utilized, the separate interconnects 130 may not be needed (since the build-up layers may be disposed directly over the die 110).

In addition to interconnects 130, a number of electrically conductive terminals (not shown in figures) may be disposed on the opposing side 124 of substrate 120. These terminals can be used to form electrical interconnects with the next-level component (e.g., motherboard or other circuit board). The terminals on the substrate's second side 124 may comprise any suitable structures and/or materials capable of forming electrical connections with the next-level component, such as, for example, lands, pins, solder bumps, Copper columns, or combinations of these and/or other structures.

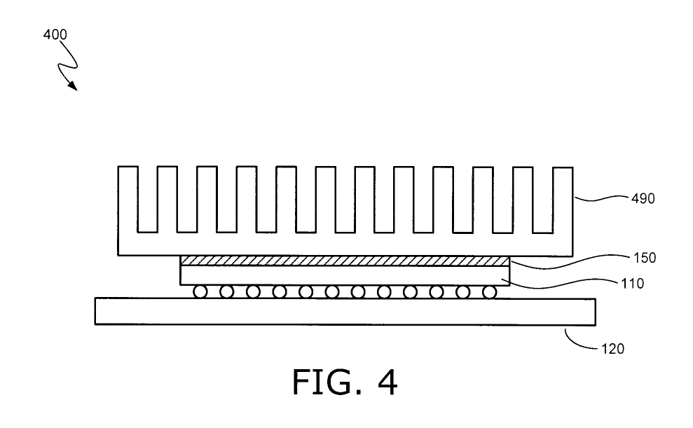

As was also mentioned above, the IC package 100 includes a thermal solution. In the embodiment of FIG. 1, the thermal solution comprises a heat spreader 140. The heat spreader 140 may also function as a lid over the die 110, and this type of heat spreader is sometimes referred to as an “integrated heat spreader” or “IHS.” Heat spreader 140 is thermally coupled to the die 110, and the heat spreader assists in removing heat generated by the die 110 during operation and transferring this heat to the surrounding environment (or otherwise dissipating this heat). The heat spreader 140 may comprise any suitable thermally conductive material, such as, for example, Copper or a Copper alloy. In one embodiment, the lid or heat spreader 140 may be mechanically coupled with the substrate's first surface 122 by, for example, a layer of adhesive 145 (e.g., an epoxy). The adhesive layer 145 is disposed between the substrate surface 122 and the lower end of a downwardly-extending wall 148 disposed about a periphery of the heat spreader 140 (or at least a portion of the heat spreader's periphery). According to another embodiment, a heat sink (not shown in FIG. 1) may be disposed over and thermally coupled to the heat spreader 140. Alternatively, in yet another embodiment, a heat sink may be directly thermally coupled with the die, in which case a heat spreader may be omitted, and this embodiment is further described below with respect to FIG. 4.

As set forth above, an oil or wax TIM 150 thermally couples the heat spreader 140 to IC die 110. In one embodiment, the TIM layer 150 comprises any material capable of thermally coupling the heat spreader 140 to die 110. In another embodiment, the TIM layer 150 comprises any liquid that wets surfaces of both the die and heat spreader. In a further embodiment, the TIM layer 150 comprises a substance that is a liquid at room temperature and at an operating temperature of the die. In yet another embodiment, the TIM layer 150 comprises a substance that is a solid at room temperature, but in some embodiments this substance may transform into a liquid state at the die's operating temperature. In yet a further embodiment, the TIM layer 150 comprises any substance capable of withstanding temperatures to which the package 100 is exposed during assembly (e.g., reflow processes). According to one embodiment, the TIM layer 150 comprises an oil, and according to another embodiment the TIM layer 150 comprises a wax.

As described above, both solders and thermally conductive polymers have been used as thermal interface materials in IC packaging. To mitigate stress, a solder TIM will often be on the order of several hundreds of microns thick. For a polymer TIM, the thickness may also be on the order of several hundreds of microns thick in order to accommodate fillers added to the polymer material to enhance thermal conductivity. These thick bond lines between the IC die and heat spreader result in higher thermal resistances, which reduces the effectiveness of these substances as thermal interface materials in IC packaging applications.

The thermal resistance of an interface material may depend on three factors, including the thickness of the interface layer, the thermal conductivity of the interface material, and the contact resistances between the interface layer and the opposing solid surfaces to which it is coupled. If the thermal interface material wets the opposing solid surfaces, the contact resistance is minimal and the bond-line thickness and thermal conductivity may have greater significance. In this circumstance, the equation below may be used to compare the performance of TIM layer 150 to that of a traditional solder:

(t/k)_{TIM}=(t/k)_{SOLDER}

where “t” is the bond-line thickness and “k” is the thermal conductivity. Therefore, according to some embodiments, in order to match the thermal performance of solder, the following relationships may be used for oil and wax, respectively:

t_{OIL}=k_{OIL}×(t/k)_{SOLDER}

t_{WAX}=k_{WAX}×(t/k)_{SOLDER}

The thickness of a solder TIM will vary depending upon the particular application; however, a bond-line thickness of approximately 200 microns (μm) for a solder TIM would be common in some applications. Assuming, for example, a solder TIM of 200 μm in thickness (t_{SOLDER}) and having a thermal conductivity (k_{SOLDER}) of approximately 30 W/m-° K, and comparing this to an oil assumed to have a thermal conductivity (k_{OIL}) of approximately 0.18 W/m-° K (the thermal conductivity of polyalphaolefin), a bond-line thickness for oil (t_{OIL}) of approximately 1.2 μm can be obtained. Thus, although the thermal conductivity of oil is substantially less than that of solder, because the oil provides minimal contact resistances due to its wetting ability, a very thin bond-line thickness can be achieved with oil while obtaining substantially the same thermal effectiveness as solder. As the reader will appreciate, the actual thermal conductivity of oil will vary with the type of oil that is used in a particular application.

Continuing with the example above, but comparing this solder to a wax having a thermal conductivity (k_{WAX}) of 2.1 W/m-° K (the thermal conductivity of candelilla wax), a bond-line thickness (t_{WAX}) of approximately 14 μm can be obtained. As before, it should be understood that the actual thermal conductivity of wax will vary with the type of wax that is used in a particular application. As was the case for oil, although the thermal conductivity of wax is substantially less than that of solder, a very thin bond-line thickness can be achieved with wax while obtaining substantially the same thermal effectiveness as solder. However, some waxes may be a solid at room temperature, but in one embodiment a wax can be changed to a liquid state during assembly in order to wet the mating solid surfaces, and according to another embodiment a wax can change to a liquid state at the operating temperature of the die.

Any suitable types of oils and waxes may be used for the TIM layer 150. Suitable oils may include those refined from petroleum, such as paraffinic oils and naphthenic oils, as well as vegetable based oils. Suitable oils may also include synthetic oils, such as synthesized hydrocarbons (e.g., polyalphaolefins), organic esters, polyglycols, and silicones. The oil, whether derived from petroleum or vegetable oil or a synthetic oil, may include one or more additives to alter one or more characteristics of the oil (e.g., viscosity, viscosity index, modulus, coefficient of thermal expansion, thermal conductivity, etc.). Suitable waxes may include natural waxes, such as candelilla wax, and synthetic waxes. Whether a natural or synthetic wax is used, the wax may also include one or more additives to alter one or more the wax's characteristics (e.g., melting temperature, thermal conductivity, modulus, coefficient of thermal expansion, etc.).

The oil or wax TIM layer 150 may be disposed between the die 110 and heat spreader 140 using any suitable technique. For example, an oil layer may be sprayed on, whereas a wax material may be sprayed on (if in liquid form) or applied as a pre-form (in solid form). As suggested above, where a wax TIM layer 150 is applied in solid form during assembly, this solid wax layer may melt to a liquid state during a later assembly step (e.g., a solder reflow process) and/or during operation of the die 110. For oil, according to some embodiments, the TIM layer 150 may have a bond-line thickness in a range of approximately 5 μm, or less. For wax, according to some embodiments, the TIM layer 150 may have a bond-line thickness in a range of approximately 30 μm, or less. However, as the examples above suggest, it should be understood that the actual thickness of the TIM layer 150 will depend upon the thermal conductivity of the particular oil or wax that is employed, as well as other factors.

In another embodiment, as illustrated in FIG. 2, a first metal layer 270a is disposed on at least a portion of the upper surface 112 of the die 110, and the TIM layer 150 contacts and perhaps wets the first metal layer 270a. In a further embodiment, a second metal layer 270b is disposed on at least a portion of the lower surface 144 of the heat spreader 140, and the TIM layer 150 contacts and perhaps wets the second metal layer 270b. According to one embodiment, the first and second metal layers 270a, 270b comprise relatively soft metals, such as Gold, Lead, or Indium, and in some embodiments these relatively soft metal layers can compensate for warpage of the die 110 and/or heat spreader 140 (or perhaps warpage of substrate 120). In one embodiment, the first and second metal layers 270a, 270b comprise the same material; however, in other embodiments the first and second metal layers may comprise different materials. It should be noted that FIG. 2 shows a portion of an IC assembly that generally corresponds to that denoted by circle 5 in FIG. 1.

In a further embodiment, as illustrated in FIG. 3, a gasket 380 may be disposed about a perimeter of the die 110 to assist in containing the TIM layer 150 between the die and heat spreader 140. The gasket 380 may also contact the lower surface 144 of heat spreader 140, as well as the inner surface of the outer wall 148 extending down from the heat spreader's lower surface. It should be noted that FIG. 3 shows a portion of an IC assembly that generally corresponds to that denoted by circle 5 in FIG. 1.

According to one embodiment, the gasket 380 comprises a solid material in the form of an O-ring (or other similar structure) inserted around the die 110 and perhaps abutting against surfaces of the heat spreader 140, as described above. In another embodiment, the gasket 380 is dispensed as a liquid sealant that subsequently cures into a solid form. Materials believed suitable for gasket 380 include rubber materials and silicones.

It should be understood, however, that gasket 380 is not required to practice the disclosed embodiments. According to other embodiments, the TIM layer 150 is retained in the space between the die 110 and heat spreader 140 without the use of a gasket. For example, surface tension may assist in retaining the TIM layer 150 between the opposing die and heat spreader surfaces.

According to yet another embodiment, an oil or wax TIM is employed to directly attach a heat sink to a die. This is illustrated in FIG. 4, where a heat sink 490 has been thermally coupled directly to the die 110 by an oil or wax TIM layer 150. The assembly 400 of FIG. 4 does not include a heat spreader (such as heat spreader 140 shown in FIGS. 1-3). Relatively soft metal layers may be applied to the upper die surface and/or a portion of the heat sink's lower surface in a manner similar to the embodiment of FIG. 2 described above. Heat sink 490 may comprise any suitable type of passive heat exchanger and may be comprised of any suitable thermally conductive materials. For example, the heat sink 490 may comprise a multi-fin heat exchanger, as shown in FIG. 4, a multi-pin heat exchanger, a cold plate, etc. Suitable thermally conductive materials for construction of heat sink 490 include Copper and Copper alloys. In yet a further embodiment, an active thermal component (not shown in figures), such as a heat pipe or micro-channel cold plate for fluid cooling, may be thermally coupled directly to the die 110 by an oil or wax TIM layer 150.

In a further embodiment, a heat sink may be attached to the heat spreader 140 shown in the embodiment of FIG. 1. In yet another embodiment, an active thermal component, such as a heat pipe or micro-channel cold plate, may be attached to the heat spreader 140. Where another thermal component—whether a heat sink or other passive cooling device, or an active cooling device—is coupled with the heat spreader 140, an oil or wax TIM layer may also be employed to thermally couple the additional thermal component to the IC package 100. Thus, an IC assembly may include two (or more) oil or wax TIM layers, and these TIM layers may be the same (e.g., both oil or both wax) or different (e.g., one oil, the other wax).

In view of the above-described embodiments, advantages of the disclosed oil and wax thermal interface materials will be apparent. As previously described, an oil or wax TIM layer may exhibit a thermal performance that is comparable to, or perhaps better than, that of traditional thermal interface materials (although in other embodiments an oil or wax TIM layer may exhibit a thermal performance that is less than that of traditional thermal interface materials). Also, an oil or wax thermal interface material may provide a cost benefit in comparison to some materials, such as Indium-based solders. Further, the use of an oil or wax TIM layer can be utilized with current process flows and tooling or with minor modifications to current process flows and tooling. In addition, the use of an oil or wax TIM layer can make removal of a heat spreader or other components relatively easy, thereby facilitating re-work and/or replacement of a defective part.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. An assembly comprising:
a substrate having an first surface and an opposing second surface, the second surface including a number of electrically conductive terminals;
an integrated circuit die having a lower surface facing the substrate's first surface and an opposing upper surface, the die electrically coupled with the substrate;
a thermal component having a lower surface facing the die's upper surface; and
a layer of oil disposed between the die and the thermal component, the oil layer wetting both the die's upper surface and the thermal component's lower surface.

2. The assembly of claim 1, wherein the oil comprises a substance selected from a group consisting of oils derived from petroleum, oils derived from vegetables, and synthetic oils.

3. The assembly of claim 1, wherein the oil layer has a thickness in a range up to approximately 5 μm.

4. The assembly of claim 1, further comprising a gasket disposed about a perimeter of the die, the gasket to retain the oil layer between the die and thermal component.

5. The assembly of claim 1, further comprising:
a layer of a first metal disposed on at least a portion of the die's upper surface; and
a layer of a second metal disposed on a least a portion of the thermal component's lower surface;
wherein the oil layer wets both the first metal layer and the second metal layer.

6. The assembly of claim 5, wherein the first metal and the second metal comprise gold.

7. The assembly of claim 5, wherein the first and second metals are different.

8. The assembly of claim 1, wherein the thermal component comprises a heat spreader or a heat sink.

9. An assembly comprising:
a substrate having a first surface and an opposing second surface, the second surface including a number of electrically conductive terminals;
an integrated circuit die having a lower surface facing the substrate's first surface and an opposing upper surface, the die electrically coupled with the substrate;
a thermal component having a lower surface facing the die's upper surface; and
a layer of wax disposed between the die and the thermal component, the wax layer thermally coupling the die's upper surface to the thermal component's lower surface.

10. The assembly of claim 9, wherein the wax layer is in a liquid state during attachment of the thermal component to the die and the wax layer wets both the die's upper surface and the thermal component's lower surface.

11. The assembly of claim 9, wherein the wax is in a solid state at room temperature and wherein the wax is in a liquid state at an operating temperature of the die.

12. The assembly of claim 9, wherein the wax comprises a substance selected from a group consisting of natural waxes and synthetic waxes.

13. The assembly of claim 9, wherein the wax layer has a thickness in a range up to approximately 30 μm.

14. The assembly of claim 9, further comprising a gasket disposed about a perimeter of the die, the gasket to retain the wax layer between the die and thermal component.

15. The assembly of claim 9, further comprising:
a first layer of gold disposed on at least a portion of the die's upper surface; and
a second layer of gold disposed on a least a portion of the thermal component's lower surface;
wherein the wax layer is disposed between the first and second gold layers and wherein the wax layer wets the first and second gold layers when in a liquid state.

16. The assembly of claim 9, wherein the thermal component comprises a heat spreader or a heat sink.
